(19) United States
(12) Patent Application Publication
(10) Pub. No.: US 2010/0141323 A1
(43) Pub. Date: Jun. 10, 2010

(54) DELAY LINE

(76) Inventor: Kyung-Hoon KIM, Gyeonggi-do (KR)

Correspondence Address: IP & T Law Firm PLC, 7700 Little River Turnpike, Suite 207, Annandale, VA, 22003, US

(21) Appl. No.: 12/425,710

(22) Filed: Apr. 17, 2009

(30) Foreign Application Priority Data
Dec. 5, 2008 (KR) 10-2008-0123476

(51) Int. Cl. H03H 11/26

(52) U.S. Cl. 327/261

(57) ABSTRACT

A delay line has a high response speed by minimizing the amount of loading on an input node and an output node while delaying an input signal over a wide variation range. The delay line includes a forward delay unit configured to determine the length of a forward delay path passing an input signal in response to a delay control code, a reverse delay unit configured to receive an output signal of the forward delay unit, and to output a delayed input signal through a reverse delay path that is as long as the length of the forward delay path determined by the delay control code, and a transfer unit configured to transfer the output signal of the forward delay unit from a turn point determined by the delay control code to the reverse delay unit.

### CROSS-REFERENCE TO RELATED APPLICATIONS

The present invention claims priority of Korean patent application number 10-2008-0123476, filed on Dec. 5, 2008 which is incorporated by reference in its entirety.

### BACKGROUND OF THE INVENTION

The present invention relates to semiconductor design technologies, and more particularly, to a delay line that is provided in a semiconductor device to delay an input signal.

A synchronous semiconductor memory device, such as a Double Data Rate Synchronous Dynamic Random Access Memory (DDR SDRAM), performs data transmission with external devices by using an internal clock synchronized with an external clock inputted from the external device, such as a memory controller (CTRL). The time synchronization between the external clock applied from the external device to the semiconductor memory device and the data outputted from the semiconductor memory device are very important for stable data transmission between the semiconductor memory device and the external device.

At this point, because the external clock is applied to the semiconductor memory device as the internal clock, the internal clock is synchronized with the external clock when the external clock is applied to the semiconductor device. However, the inputted internal clock becomes out-of-sync from the external clock because of a delay through the respective components of the semiconductor memory device.

Thus, for stable transmission of data outputted from the semiconductor memory device, the internal clock and the external clock must be synchronized with each other by inversely compensating the internal clock by the time to load the data into a bus, so that the delay in the internal clock through the respective components of the semiconductor memory device is located accurately at the edge or center of the external clock applied from the external device.

As mentioned above, the internal clock must be inversely compensated by the time to load the data into a bus in order to be synchronized with the external clock. Herein, the internal clock is generated by delaying the external clock applied from the external device through a delay circuit that models the respective components of the semiconductor memory device. The delay value of the delay circuit modeling the respective components of the semiconductor memory device is not variable. A method that further delays the phase of the internal clock until the phase of the internal clock and the phase of the external clock are synchronized with each other is therefore used.

However, the phase difference between the internal clock and the external clock cannot be precalculated and may vary without limitation depending on the driving environment of the semiconductor memory device. Therefore, in order to accurately synchronize the phase of the internal clock with the phase of the external clock, the internal clock must be delayed through a delay circuit whose delay value varies freely according to a control signal.

Also, when the driving environment of the semiconductor memory device is at its worst, the phase difference between the internal clock and the external clock may approach one clock cycle (1tck). Therefore, in order to satisfy this phase difference and to also synchronize the phase of the internal clock with the phase of the external clock accurately in that circumstance, the internal clock must be delayed through a delay circuit that has a very wide range of variable delay values according to a control signal.

Thus, the following delay line satisfying all of the requirements of the delay circuit is used to synchronize the phase of the internal clock with the phase of the external clock.

FIG. 1 is a circuit diagram of a conventional Multi Input Single Output (MISO) delay line. Referring to FIG. 1, the conventional MISO delay line includes a plurality of delay units UNIT_DELAY<1:N>.

The conventional MISO delay line receives an input signal INPUT_SIG through each of a plurality of signal input nodes INPUT_ND<1:N> provided respectively at the plurality of delay units UNIT_DELAY<1:N>, and outputs a final delay signal FIN_DLY_INPUT_SIG through a signal output node OUTPUT_ND of a first delay unit UNIT_DELAY<1> among the delay units UNIT_DELAY<1:N>.

Specifically, the delay units UNIT_DELAY<1:N> provided at the MISO delay line respectively have the signal input nodes INPUT_ND<1:N> configured to receive the input signal INPUT_SIG applied from the outside of the MISO delay line, and a plurality of control signal input nodes C_ND<1:N>configured to respectively receive a plurality of control signals CON<1:N>applied from the outside of the MISO delay line.

Also, the signal output node OUTPUT_ND configured to output the final delay signal FIN_DLY_INPUT_SIG, i.e., DLY_INPUT_SIG<1>, to the outside of the MISO delay line is provided only at the first delay unit UNIT_DELAY<1> among the delay units UNIT_DELAY<1:N>.

That is, the delay units UNIT_DELAY<2:N> other than the first delay unit UNIT_DELAY<1> among the delay units UNIT_DELAY<1:N> output their respective output signals DLY_INPUT_SIG<2:N> to their respective previous delay units UNIT_DELAY<1:N−1>, not to the outside of the MISO delay line.

Herein, in response to the respective control signals CON<1:N> inputted through the respective control signal input nodes C_ND<1:N>, the respective delay units UNIT_DELAY<1:N> determine whether to delay the input signal INPUT_SIG applied through the respective signal input nodes INPUT_ND<1:N>. That is, only one of the control signals CON<1:N> applied respectively to the delay units UNIT_DELAY<1:N> is activated and the others are deactivated. Herein, the delay units, to which the deactivated control signals are applied, wait to receive signals from their respective next delay units without performing any operation regardless of the application of the input signal INPUT_SIG. That is, the delay units receiving the deactivated control signals do not perform any operation, whereas the delay unit receiving the activated control signal delays the applied input signal INPUT_SIG by a predetermined delay value and transfers the delayed input signal to a previous delay unit.

For example, when only the fifth control signal CON<5> among the control signals CON<1:N> is activated to a logic low level and the other control signals are deactivated to a logic high level, the delay units UNIT_DELAY<6:N> next to the fifth delay unit UNIT_DELAY<5> among the delay units UNIT_DELAY<1:N> do not perform a delay operation in response to the applied input signal INPUT_SIG and do not perform any operation since signals are not received from the next delay units UNIT_DELAY<7:N) of the delay units UNIT_DELAY<6:N>.

On the other hand, the fourth to first delay units UNIT_DELAY<4:1>, which are positioned previously to the fifth delay unit UNIT_DELAY<5> do not perform a delay operation in response to the applied input signal INPUT_SIG, such as the delay units UNIT_DELAY<6:N>next to the fifth delay unit UNIT_DELAY<5>, but the input signal INPUT_SIG is inputted through the fifth delay unit UNIT_DELAY<5> to output a delay signal DLY_INPUT_SIG<5>. Delay signals DLY_INPUT_SIG<5:2> are sequentially outputted from the fifth to second delay units UNIT_DELAY<5:2> to the fourth to first delay units UNIT_DELAY<4:1>. Therefore, the fifth to first delay units UNIT_DELAY<5:1> delay the input signal INPUT_SIG by a predetermined time, so that the final delay signal FIN_DLY_INPUT_SIG becomes a signal that is generated by delaying the input signal INPUT_SIG by a time corresponding to the five delay units.

In this way, the MISO delay line can freely control the delay degree of the input signal INPUT_SIG according to the control signals CON<1:N>. Also, the MISO delay line can freely change the total number of the delay units used among the delay units UNIT_DELAY<1:N> by controlling the value of ‘N’. Therefore, the MISO delay line can control the maximum delay value of the delay line freely according to the value of ‘N’. Thus, the MISO delay line satisfies all of the requirements of the delay circuit, thereby making it possible to synchronize the phase of the internal circuit with that of the external circuit.

However, in the MISO delay line, all of the delay units UNIT_DELAY<1:N> receive the input signal INPUT_SIG. Thus, as the value of ‘N’ increases and the total length of the delay line increases, the size of a driver driving the input signal INPUT_SIG to the delay line must increase in order to stably transfer the input signal INPUT_SIG to the delay units UNIT_DELAY<1:N>.

Thus, the driver driving the input signal INPUT_SIG to the delay line must always be turned on during the use of the delay line. Therefore, as the size of the driver increases, the consequent power consumption increases.

Also, as the total length of the delay line increases with an increase in the value of ‘N’, the length of a line through which the input signal INPUT_SIG must pass increases accordingly and the loading on the input signal INPUT_SIG increases accordingly. This makes it impossible for the delay line to operate at a high response speed, thus making it impossible to apply the MISO delay line to a semiconductor memory device that operates at a higher speed.

Also, since the input signal INPUT_SIG is inputted in parallel to the delay units UNIT_DELAY<1:N>, when the MISO delay is applied to a high-speed semiconductor memory device, an Electro Magnetic Interference (EMI) is caused therebetween.

FIG. 2 is a circuit diagram of a conventional Single Input Multi Output (SIMO) delay line. Referring to FIG. 2, the conventional SIMO delay line includes a plurality of delay units UNIT_DELAY<1:N>.

The conventional SIMO delay line receives an input signal INPUT_SIG through a signal input node INPUT_ND of a first delay unit UNIT_DELAY<1> among the plurality of delay units UNIT_DELAY<1:N>, and outputs a plurality of delay signals DLY_INPUT_SIG<1:N> through a plurality of signal output nodes OUTPUT_ND<1:N> provided respectively at the delay units UNIT_DELAY<1:N>. Herein, according to a plurality of control signals CON<1:N> applied to a plurality of control nodes MUX_C_ND, any one of the delay signals DLY_INPUT_SIG<1:N> is selected to output a final delay signal FIN_DLY_INPUT_SIG through a final signal output node MUX_OUTPUT_ND.

Specifically, the delay units UNIT_DELAY<1:N> provided at the SIMO delay line respectively have a plurality control signal input nodes C_ND<1:N> configured to receive the control signals CON<1:N> applied from the outside of the SIMO delay line, and the signal output nodes OUTPUT_ND<1:N> to which the delay signals DLY_INPUT_SIG<1:N> of the respective delay units are applied.

Also, the signal input node INPUT_ND configured to receive the input signal INPUT_SIG from the outside of the SIMO delay line is provided only at the first delay unit UNIT_DELAY<1> among the delay units UNIT_DELAY<1:N>.

Also, a multiplexer 200 is further provided to select one of the output signals of the delay units UNIT_DELAY<1:N> in response to the control signals CON<1:N> to output the selected signal as the final delay signal FIN_DLY_INPUT_SIG to the outside of the SIMO delay line.

That is, the delay units UNIT_DELAY<2:N> other than the first delay unit UNIT_DELAY<1> among the delay units UNIT_DELAY<1:N> do not receive the input signal INPUT_SIG directly from the outside of the SIMO delay line, but receive the output signals DLY_INPUT_SIG<1:N−1> of the previous delay units UNIT_DELAY<1:N−1> of the delay units UNIT_DELAY<2:N>.

Herein, in response to the respective control signals CON<1:N> inputted through the respective control signal input nodes C_ND<1:N>, the respective delay units UNIT_DELAY<1:N> determine whether to delay the input signal INPUT_SIG applied through the signal input node INPUT_ND and the delay signals DLY_INPUT_SIG<1:N−1> outputted from the previous delay units UNIT_DELAY<1:N−1>. That is, the delay units corresponding to the activated control signals among the control signals CON<1:N>, applied respectively to the delay units UNIT_DELAY<1:N>, delay signals applied from the signal input node or the previous delay unit by a predetermined delay value and transfer the delayed signal to the next delay unit of the corresponding delay unit, whereas the delay units corresponding to the deactivated control signals among the control signals CON<1:N> do not perform any operation regardless of the application of the signals from the signal input unit or the previous delay unit.

For example, when only the first to fifth control signals CON<1:5> among the control signals CON<1:N> are activated to a logic high level and the other control signals CON<6:N> are deactivated to a logic low level, the first to fifth delay units UNIT_DELAY<1:5> delay the input signal INPUT_SIG by a predetermined delay value. The delay units UNIT_DELAY<6:N> other than the first to fifth delay units UNIT_DELAY<1:5> receive the delay signal DLY_INPUT_SIG<5> through the fifth delay unit UNIT_DELAY<5> but do not perform a delay operation. In this state, in response to the first to fifth control signals CON<1:5> activated to a logic high level among the control signals CON<1:N>, the multiplexer 200 selects the delay signal DLY_INPUT_SIG<5> outputted from the fifth delay unit UNIT_DELAY<5> and outputs the selected signal as the final delay signal FIN_DLY_INPUT_SIG to the outside of the SIMO delay line.

In this way, the SIMO delay line can freely control the delay degree of the input signal INPUT_SIG according to the control signals CON<1:N>. Also, the SIMO delay line can freely change the total number of the delay units used among the delay units UNIT_DELAY<1:N> by controlling the value of ‘N’. Therefore, the SIMO delay line can control the maximum delay value of the delay line freely according to the value of ‘N’. Thus, the SIMO delay line satisfies all of the requirements of the delay circuit, thereby making it possible to synchronize the phase of the internal circuit with that of the external circuit.

However, since the SIMO delay line outputs the delay signals DLY_INPUT_SIG<1:N> respectively from the delay units UNIT_DELAY<1:N> and outputs the final delay signal FIN_DLY_INPUT_SIG through a multiplexing operation of selecting one of the delay signals DLY_INPUT_SIG<1:N>, all of the delay units UNIT_DELAY<1:N> and the multiplexer 200 must be provided in the delay line.

Accordingly, the multiplexer 200 must additionally be designed, and many corresponding logic gate units must be added to the delay line. In addition, the multiplexing operation must always be performed by the multiplexer 200, thus making it impossible for the delay line to operate at a high response speed. This makes it impossible for the SIMO delay line to be applied to a semiconductor memory device that operates at a relatively higher speed.

The aforesaid limitations become more severe when the total length of the delay line increases with an increase in the value of ‘N’. As the total length of the delay line increases with an increase in the value of ‘N’, more delay signals are outputted from more delay units to apply more loading on the multiplexing operation of the multiplexer 200, thus reducing the response speed of the delay line.

### SUMMARY OF THE INVENTION

Embodiments of the present invention are directed to providing a delay line that has a high response speed by minimizing the amount of loading on an input node and an output node while delaying an input signal in a wide variation range.

In accordance with an aspect of the present invention, there is provided a delay line, including a forward delay unit configured to determine the length of a forward delay path passing an input signal in response to a delay control code; a reverse delay unit configured to receive an output signal of the forward delay unit, and to output a delayed input signal through a reverse delay path that is as long as the length of the forward delay path determined by the delay control code; and a transfer unit configured to transfer the output signal of the forward delay unit from a turn point determined by the delay control code to the reverse delay unit.

In accordance with another aspect of the present invention, there is provided a delay line which includes a plurality of chain-connected unit delay blocks, each of said plurality of chain-connected unit delay blocks including a forward delay unit configured to delay an input signal received from a previous unit delay block of the plurality of chain-connected unit delay blocks in response to a delay control code corresponding to the unit delay block; and a reverse delay unit configured to delay an input signal received from the forward delay unit or a next unit delay block of the plurality of chain-connected unit delay blocks in response to a delay control code corresponding to the next unit delay block.

In accordance with another aspect of the present invention, there is provided a delay line which includes a plurality of chain-connected unit delay blocks, each of said plurality of chain-connected unit delay blocks including a forward transfer unit configured to output a forward signal received from a previous unit delay block of the plurality of chain-connected unit delay blocks in response to a delay control code corresponding to the corresponding unit delay block; a reverse transfer unit configured to output a reverse signal received from a next unit delay block of the plurality of chain-connected unit delay blocks and a turn signal to the previous unit delay block; and a turn transfer unit configured to output an output signal of the forward transfer unit as the turn signal in response to a delay control code corresponding to the next unit delay block.

In accordance with another aspect of the present invention, there is provided a method for operating a delay line which includes a plurality of chain-connected unit delay blocks, each having a forward input node, a forward output node, a reverse input node, and a reverse output node. The method including outputting a signal applied to the forward input node to the forward output node in response to a delay control code corresponding to the corresponding unit delay block; outputting a signal applied to the reverse input node to the reverse output node; and outputting a signal applied to the forward output node to the reverse input node in response to a delay control code corresponding to the next unit delay block.

### BRIEF DESCRIPTION OF THE DRAWINGS

FIG. 1 is a circuit diagram of a conventional Multi Input Single Output (MISO) delay line.

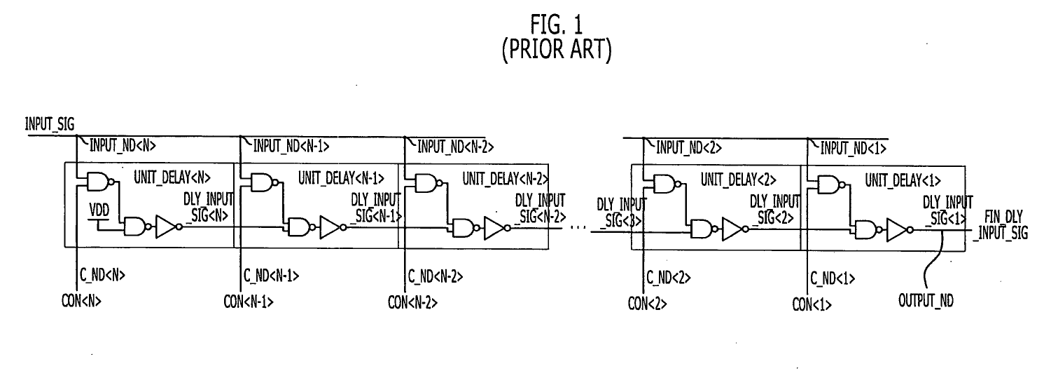

FIG. 2 is a circuit diagram of a conventional Single Input Multi Output (SIMO) delay line.

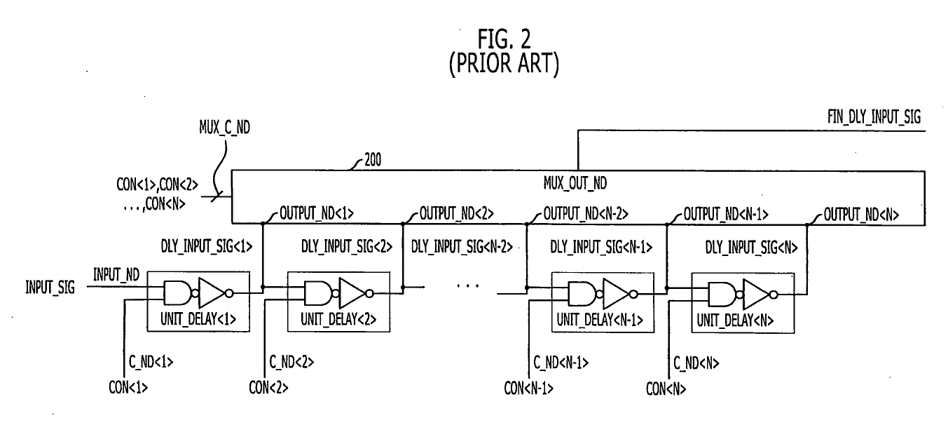

FIG. 3 is a block diagram of a delay line in accordance with an embodiment of the present invention.

FIG. 4 is a block diagram of a delay line in accordance with another embodiment of the present invention.

FIG. 5 is a circuit diagram of a delay line in accordance with an embodiment of the present invention.

FIGS. 6A and 6B are circuit diagrams of a unit delay block provided in the delay line in accordance with an embodiment of the present invention.

### DESCRIPTION OF SPECIFIC EMBODIMENTS

Other objects and advantages of the present invention can be understood by the following description, and become apparent with reference to the embodiments of the present invention. The invention may, however, be embodied in many different forms and should not be construed as being limited to the embodiments set forth herein; rather, these embodiments are provided so that this disclosure will be thorough and complete, and will fully convey the concept of the invention to those skilled in the art.

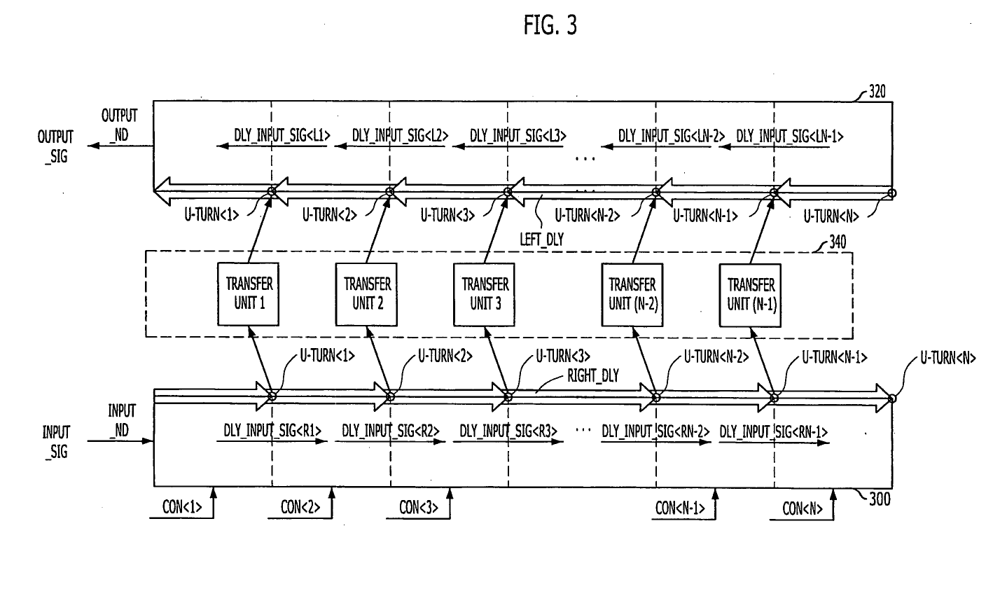

FIG. 3 is a block diagram of a delay line in accordance with an embodiment of the present invention. Referring to FIG. 3, the delay line in accordance with this embodiment of the present invention includes a forward delay unit 300, a reverse delay unit 320, and a transfer unit 340.

The forward delay unit 300 determines the length of a forward delay path RIGHT_DLY passing an input signal INPUT_SIG in response to delay control codes CON<1:N>. The reverse delay unit 320 receives forward delay signals DLY_INPUT_SIG<R1:RN> that have passed through the forward delay unit 300, and outputs reverse delay signals DLY_INPUT_SIG<R1:RN> as an output signal OUTPUT_SIG through a reverse delay path LEFT_DLY that is as long as the length of the forward delay path RIGHT_DLY determined by the delay control codes CON<1:N>. The transfer unit 340 transfers the delay signals DLY_INPUT_SIG<R1:RN> that have passed through the forward delay unit 300 from turn points U-TURN<1:N> determined by the delay control codes CON<1:N> to the reverse delay unit 320.

The forward delay unit 300 receives the input signal INPUT_SIG through a signal input node INPUT_ND, passes the input signal INPUT_SIG through the forward delay path RIGHT_DLY whose length varies in response to the delay control codes CON<1:N>, and outputs the results DLY_INPUT_SIG<R1:RN> to the transfer unit 340. Herein, the length of the forward delay path RIGHT_DLY varies by a unit delay in response to the delay control codes CON<1:N>.

The reverse delay unit 320 receives the results DLY_INPUT_SIG<R1:RN> that have passed through the forward delay path RIGHT_DLY from the transfer unit 340 at the turn points U-TURN<1:N>, passes the results DLY_INPUT_SIG<R1:RN> through the reverse delay path LEFT_DLY corresponding to the delay control codes CON<1:N>, and outputs the output signal OUTPUT_SIG to a signal output node OUTPUT_ND. Herein, the length of the reverse delay path LEFT_DLY varies by a unit delay in response to the delay control codes CON<1:N>.

An operation of the delay line in accordance with this embodiment of the present invention will be described below on the basis of the above configuration.

First, the delay control codes CON<1:N> include a plurality of bits and the delay control code CON<1> of the least significant bit LSB to the delay control code CON<N> of the most significant bit MSB may sequentially have a value of ‘1’.

For example, when the delay control code CON<5> of the fifth bit among the delay control codes CON<1:N> has a value of ‘1’, the delay control code CON<1> of the least significant bit LSB to the delay control code CON<5> of the fifth bit unconditionally have a value of ‘1’.

Also, the length of the forward delay path RIGHT_DLY and the length of the reverse delay path LEFT_DLY increase as the number of the bits having a value of ‘1’ in the delay control codes CON<1:N> increases.

For example, when the delay control code CON<1> of the least significant bit LSB to the delay control code CON<7> of the seventh bit have a value of ‘1’, the forward delay path RIGHT_DLY and the reverse delay path LEFT_DLY become longer than the length of the forward delay path RIGHT_DLY and the reverse delay path LEFT_DLY when the delay control code CON<1> of the least significant bit LSB to the delay control code CON<5> of the fifth bit have a value of ‘1’.

Also, the length of the forward delay path RIGHT_DLY and the length of the reverse delay path LEFT_DLY, which vary in response to the same delay control codes CON<1:N>, are identical to each other, but the delay value of the forward delay path RIGHT_DLY and the delay value of the reverse delay path LEFT_DLY may vary according to the design method. That is, when the unit delay in the forward delay path RIGHT_DLY and the unit delay in the reverse delay path LEFT_DLY are designed to have different values, the length of the forward delay path RIGHT_DLY and the length of the reverse delay path LEFT_DLY are identical to each other, but the delay value of the forward delay path RIGHT_DLY and the delay value of the reverse delay path LEFT_DLY are different from each other.

Likewise, when the unit delay in the forward delay path RIGHT_DLY and the unit delay in the reverse delay path LEFT_DLY are designed to have the same value, the length of the forward delay path RIGHT_DLY and the length of the reverse delay path LEFT_DLY are identical to each other and the delay value of the forward delay path RIGHT_DLY and the delay value of the reverse delay path LEFT_DLY are also identical to each other.

Specifically, the input signal INPUT_SIG applied through the signal input node INPUT_ND from the outside of the delay line first passes through the forward delay path RIGHT_DLY corresponding to the delay control codes CON<1:N>. Herein, when only the delay control code CON<1> of the least significant bit LSB to the delay control code CON<5> of the fifth bit have a value of ‘1’ and the delay control codes CON<6:N> of the other bits have a value of ‘0’, the input signal INPUT_SIG undergoes five times the delay value corresponding to the unit delay of the forward delay path RIGHT_DLY (i.e., INPUT_SIG→DLY_INPUT_SIG<R1>→DLY_INPUT_SIG<R2>→DLY_INPUT_SIG<R3>→DLY_INPUT_SIG<R4>→DLY_INPUT_SIG<R5>) prior to reaching the turn point U-TURN<5> corresponding to the delay control code CON<5> of the fifth bit.

Thereafter, the transfer unit 340 transfers the delay signal DLY_INPUT_SIG<R5> outputted from the forward delay path RIGHT_DLY at the turn point U-TURN<5> corresponding to the delay control code CON<5> of the fifth bit directly to the reverse delay path LEFT_DLY, so that the delay signal DLY_INPUT_SIG<R5> outputted from the forward delay path RIGHT_DLY passes through the reverse delay path LEFT_DLY.

Herein, since the length of the reverse delay path LEFT_DLY is identical to the length of the forward delay path RIGHT_DLY corresponding to the delay control code CON<5> of the fifth bit, the delay signal DLY_INPUT_SIG<R5> outputted from the forward delay path RIGHT_DLY through the transfer unit 340 undergoes five times the delay value corresponding to the unit delay of the reverse delay path LEFT_DLY (i.e., DLY_INPUT_SIG<L5>→DLY_INPUT_SIG<L4>→DLY_INPUT_SIG<L3>→DLY_INPUT_SIG<L2>→DLY_INPUT_SIG<L1>→OUTPUT_SIG) prior to reaching the signal output node OUTPUT_ND, so that the resultant signal is outputted to the outside of the delay line.

In this way, the input signal INPUT_SIG applied through the signal input node INPUT_ND from the outside of the delay line in accordance with the embodiment of the present invention undergoes the delay value corresponding to the length of the forward delay path RIGHT_DLY in the delay line and then undergoes the delay value corresponding to the length of the reverse delay path LEFT_DLY, so that it is delayed by a predetermined delay value and is outputted through the signal output node OUTPUT_ND to the outside of the delay line. Herein, the length of the reverse delay path LEFT_DLY and the length of the forward delay path RIGHT_DLY passing the input signal INPUT_SIG vary according to the delay control codes CON<1:N>.

Thus, the delay line in accordance with this embodiment of the present invention can freely control the delay value of the input signal INPUT_SIG according to the delay control codes CON<1:N>, and can freely change the maximum length of the forward delay path RIGHT_DLY and the maximum length of the reverse delay path LEFT_DLY by controlling the value of ‘N’. Therefore, the maximum delay value of the delay line can be freely controlled according to the value of ‘N’.

Also, since only one signal input node INPUT_ND and one signal output node OUTPUT_ND are used, even if the total length of the delay line increases with an increase in the value of ‘N’, the loading on the signal input node INPUT_ND and the loading on the signal output node OUTPUT_ND always have the same value. Thus, the response speed of the delay line can always maintain the same value regardless of the length of the delay line, so that the delay line in accordance with this embodiment of the present invention can operate stably, even in a semiconductor memory device that operates at high speeds.

As described above, this embodiment of the present invention can freely determine the delay value of the input signal INPUT_SIG in the delay line according to the delay control codes CON<1:N> and can freely control the maximum delay value of the delay line according to the value of ‘N’, thus making it possible to freely delay the input signal INPUT_SIG over a wide variation range.

Also, only one signal input node INPUT_ND and one signal output node OUTPUT_ND are used to delay the input signal INPUT_SIG, thereby minimizing the amount of loading on the signal input node INPUT_ND and the signal output node OUTPUT_ND. This makes it possible for the delay line to have a high response speed.

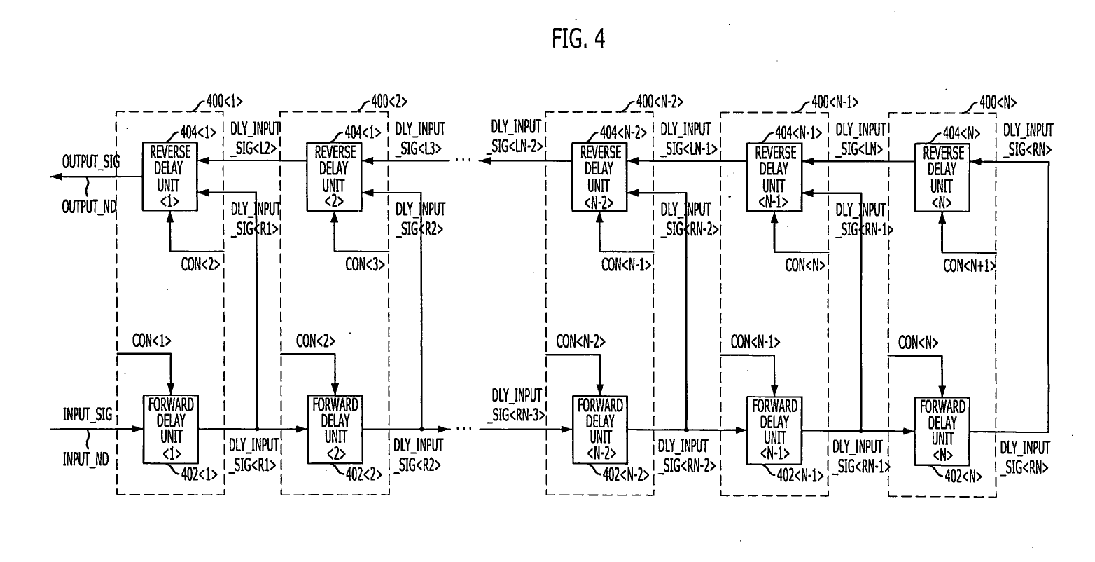

FIG. 4 is a block diagram of a delay line in accordance with another embodiment of the present invention. Referring to FIG. 4, the delay line in accordance with this embodiment of the present invention includes a plurality of chain-connected unit delay blocks 400<1:N>.

Each of the unit delay blocks 400<1:N> includes forward delay units 402<1:N> and reverse delay units 404<1:N>. The forward delay units 402<1:N> delay input signal INPUT_SIG or forward delay signals DLY_INPUT_SIG<R1:RN−1> received from a signal input node INPUT_ND or the previous unit delay blocks 400<1:N−1> in response to delay control codes CON<1:N> corresponding to the corresponding unit delay block 400<1:N>, and outputs the resulting signal to the next unit delay blocks 400<2:N>. The reverse delay units 404<1:N> delay the forward delay signals DLY_INPUT_SIG<R1:RN> having passed through the forward delay units 402<1:N> or reverse delay signals DLY_INPUT_SIG<L2:LN> received from the next unit delay blocks 400<2:N> in response to delay control codes CON<2:N> corresponding to the next unit delay blocks 400<2:N>, and outputs the resulting signal to the previous unit delay blocks 400<1:N−1> or a signal output node OUTPUT_ND.

Herein, the forward delay unit 402<1> provided at the first unit delay block 400<1> among the unit delay blocks 400<1:N> delays an input signal INPUT_SIG applied from the signal input node INPUT_ND from the outside of the delay line by a predetermined time in response to the delay control code CON<1> of the least significant bit LSB among the delay control codes CON<1:N>, and outputs the result DLY_INPUT_SIG<R1> to the next unit delay block 400<2>.

Also, the forward delay units 402<2:N−1> provided at the unit delay blocks 400<2:N−1>, other than the first unit delay block 400<1> and the last unit delay block 400<N>, delay the forward delay signals DLY_INPUT_SIG<R1:RN−2> received from the forward delay units 402<1:N−2> provided at the previous unit delay blocks 400<1:N−2> by a predetermined time in response to the delay control codes CON<2:N−1> of the bits other than the delay control code CON<1> of the least significant bit LSB and the delay control code CON<N> of the most significant bit MSB, and output the results DLY_INPUT_SIG<R2:RN−1> to the next unit delay blocks 400<3:N>.

Also, the forward delay unit 402<N> provided at the last unit delay block 400<N> among the unit delay block 400<1:N> delays the forward delay signal DLY_INPUT_SIG<RN−1> received from the forward delay unit 402<N−1> provided at the previous unit delay block 400<N−1> by a predetermined time in response to the delay control code CON<N> of the most significant bit MSB among the delay control codes CON<1:N>, and outputs the result DLY_INPUT_SIG<RN> to the reverse delay unit 404<N> provided at the corresponding unit delay block 400<N>.

Also, the reverse delay unit 404<N> provided at the last unit delay block 400<N> among the unit delay blocks 400<1:N> delays the forward delay signal DLY_INPUT_SIG<RN> received from the forward delay unit 402<N> provided at the corresponding unit delay block 400<N> by a predetermined time in response to an additional delay control code CON<N+1> determined corresponding to the delay control code CON<N> of the most significant bit MSB among the delay control codes CON<1:N>, and outputs the result DLY_INPUT_SIG<RN> to the previous unit delay block 400<N−1>.

Herein, the additional delay control code CON<N+1> has the same value as the delay control code CON<N> of the most significant bit MSB among the delay control codes CON<1:N>. That is, when the delay control code CON<N> of the most significant bit MSB among the delay control codes CON<1:N> has a value of ‘1’, the additional delay control code CON<N+1> also has a value of ‘1’ and when the delay control code CON<N> of the most significant bit MSB among the delay control codes CON<1:N> has a value of ‘0’, the additional delay control code CON<N+1> also has a value of ‘0’.

Also, the reverse delay units 404<2:N−1> provided at the unit delay blocks 400<2:N−1> other than the first unit delay block 400<1> and the last unit delay block 400<N> among the unit delay blocks 400<1:N> delay the reverse delay signals DLY_INPUT_SIG<L3:LN> received from the reverse delay units 404<3:N> provided at the next unit delay block 400<3:N> by a predetermined time in response to the bit value of the delay control codes CON<3:N> corresponding to the forward delay units 402<3:N> provided at the next unit delay blocks 400<3:N>, and outputs the results DLY_INPUT_SIG<L2:LN−1> to the previous unit delay blocks 400<1:N−2>.

Also, the reverse delay unit 404<1> provided at the first unit delay blocks 400<1> among the unit delay blocks 400<1:N> delays the reverse delay signal DLY_INPUT_SIG<L2> outputted from the reverse delay unit 404<2> provided at the next unit delay block 400<2> by a predetermined time in response to the delay control code CON<2> corresponding to the forward delay unit 402<2> provided at the next unit delay block 402<2>, and outputs the result OUTPUT_SIG through the signal output node OUTPUT_ND to the outside of the delay line.

An operation of the delay line in accordance with this embodiment of the present invention will be described below on the basis of the above configuration.

First, the delay control codes CON<1:N> include a plurality of bits and the delay control code CON<1> of the least significant bit LSB to the delay control code CON<N> of the most significant bit MSB may sequentially have a value of ‘1’.

For example, when the delay control code CON<5> of the fifth bit among the delay control codes CON<1:N> has a value of ‘1’, the delay control code CON<1> of the least significant bit LSB to the delay control code CON<5> of the fifth bit unconditionally have a value of ‘1’.

Also, the number of the unit delay blocks that pass the input signal INPUT_SIG among the unit delay blocks 400<1:N> increases as the number of the bits having a value of ‘1’ in the delay control codes CON<1:N> increases.

For example, when the delay control code CON<1> of the least significant bit LSB to the delay control code CON<5> of the fifth bit have a value of ‘1’, only the first to fifth unit delay blocks 400<1:5> among the unit delay blocks 400<1:N> are used to delay the input signal INPUT_SIG. When the delay control code CON<1> of the least significant bit LSB to the delay control code CON<7> of the seventh bit have a value of ‘1’, the first to seventh unit delay blocks 400<1:7> among the unit delay blocks 400<1:N> are used to delay the input signal INPUT_SIG. Therefore, the delay value of the input signal INPUT_SIG when the delay control code CON<1> of the least significant bit LSB to the delay control code CON<7> of the seventh bit have a value of ‘1’ is larger than the delay value of the input signal INPUT_SIG when the delay control code CON<1> of the least significant bit LSB to the delay control code CON<5> of the fifth bit have a value of ‘1’.

Also, the delay values of the input signal INPUT_SIG in the forward delay units 402<1:N> and the reverse delay units 404<1:N> may differ from each other according to the design method.

That is, when the delay corresponding to the reverse delay units 404<1:N> and the delay corresponding to the forward delay units 402<1:N> provided at the unit delay blocks 400<1:N> are designed to have different values, the reverse delay value of the input signal INPUT_SIG and the forward delay value of the input signal INPUT_SIG in the unit delay blocks 400<1:N> are different from each other.

However, when the delay corresponding to the reverse delay units 404<1:N> and the delay corresponding to the forward delay units 402<1:N> provided at the unit delay blocks 400<1:N> are designed to have the same value, the reverse delay value of the input signal INPUT_SIG and the forward delay value of the input signal INPUT_SIG in the unit delay blocks 400<1:N> are identical to each other.

Specifically, when the input signal INPUT_SIG is applied from the outside of the delay line through the signal input node INPUT_ND connected to the forward delay unit 402<1> provided at the first unit delay block 400<1> among the unit delay blocks 400<1:N>, the delay value of the input signal INPUT_SIG is determined according to the delay control codes CON<1:N>.

For example, when only the delay control code CON<1> of the least significant bit LSB to the delay control code CON<5> of the fifth bit among the delay control codes CON<1:N> have a value of ‘1’ and the delay control codes CON<6:N> of the other bits have a value of ‘0’, the forward delay units 402<1:5> and the reverse delay units 404<1:4> are enabled in response to the delay control code<1:5> having a value of ‘1’. The forward delay units 402<6:N> and the reverse delay units 404<6:N> are disabled in response to the delay control code<6:N> having a value of ‘0’.

On the other hand, the reverse delay unit 404<5> is not enabled only in response to the corresponding delay control code<6>, because it has a value of ‘0’. However, the reverse delay unit 404<5> is enabled in response to an output of the forward delay unit 404<5>.

Thus, the forward delay units 402<1:4> provided at the first to fourth unit delay blocks 400<1:4> among the unit delay blocks 400<1:N> delay the input signal INPUT_SIG or the forward delay signals DLY_INPUT_SIG<R1:R3> received from the forward delay units 402<1:3> provided at the previous unit delay blocks 400<1:3> by a predetermined time, and outputs the results DLY_INPUT_SIG<R1:R4> to the next unit delay blocks 400<2:5>.

On the other hand, the forward delay unit 402<5> provided at the fifth unit delay block 400<5> among the unit delay blocks 400<1:N> delays the forward delay signal DLY_INPUT_SIG<R4> received from the forward delay unit 402<4> provided at the previous unit delay blocks 400<4> by a predetermined time, and outputs the result DLY_INPUT_SIG<R5> to the reverse delay unit 404<5> of the corresponding unit delay blocks 400<5>.

Also, the unit delay blocks 400<6:N> other than the first to fifth unit delay blocks 400<1:5> among the unit delay blocks 400<1:N> do not perform any operation.

In this way, the input signal INPUT_SIG applied through the signal input node INPUT_ND from the outside of the delay line in accordance with the embodiment of the present invention is delayed sequentially through the forward delay units 402<1:N> provided at the unit delay blocks 400<1:N>. The delayed input signal is again delayed sequentially through the reverse delay units 404<1:N> provided at the unit delay blocks 400<1:N>, so that the delayed input signal is outputted through the signal output node OUTPUT_ND. Herein, the number of the unit delay blocks passing the input signal INPUT_SIG varies according to the delay control codes CON<1:N>.

Thus, the delay line in accordance with this embodiment of the present invention can freely control the delay value of the input signal INPUT_SIG by freely controlling the number of the unit delay blocks among the unit delay blocks 400<1:N> to delay the input signal INPUT_SIG according to the delay control codes CON<1:N>. The delay line can freely change the total number of the unit delay blocks 400<1:N> included in the delay line by controlling the value of ‘N’. Therefore, the maximum delay value of the delay line can be freely controlled according to the value of ‘N’.

Also, since only one signal input node INPUT_ND and one signal output node OUTPUT_ND are used, even though the total length of the delay line increases with an increase in the value of ‘N’, the loading on the signal input node INPUT_ND and the loading on the signal output node OUTPUT_ND always have the same value. Thus, the response speed of the delay line can always maintain the same value regardless of the length of the entire delay line, so that the delay line in accordance with this embodiment of the present invention can operate stably even in a semiconductor memory device that operates at high speeds.

As described above, this embodiment of the present invention can freely determine the delay value of the input signal INPUT_SIG in the delay line according to the delay control codes CON<1:N> and can freely control the maximum delay value of the delay line according to the value of ‘N’, thus making it possible to freely delay the input signal INPUT_SIG over a wide variation range.

Also, only one signal input node INPUT_ND and one signal output node OUTPUT_ND are used to delay the input signal INPUT_SIG, thereby minimizing the amount of loading on the signal input node INPUT_ND and the signal output node OUTPUT_ND. This makes it possible for the delay line to have a high response speed.

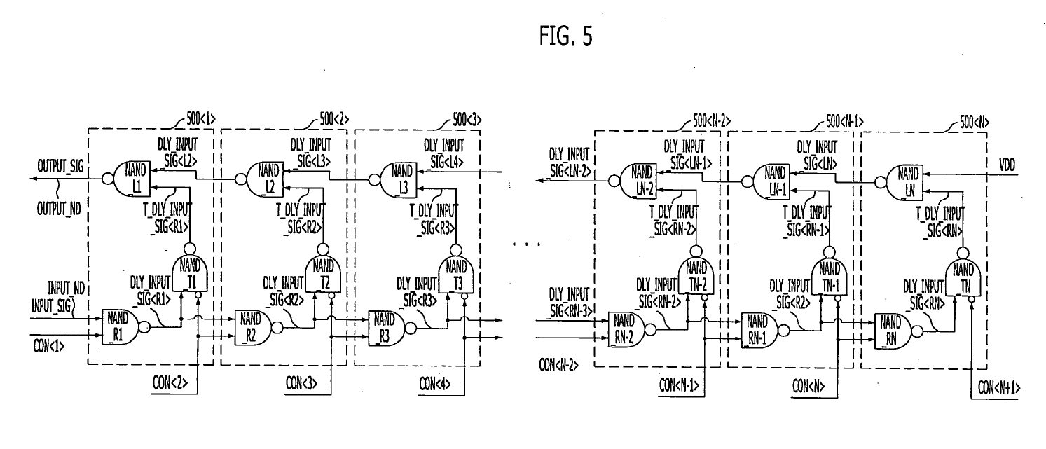

FIG. 5 is a circuit diagram of a delay line in accordance with an embodiment of the present invention.

Referring to FIG. 5, the delay line in accordance with this embodiment of the present invention includes a plurality of chain-connected unit delay blocks 500<1:N>. The unit delay blocks 500<1:N> respectively include forward NAND gates NAND_<R1:RN>, reverse NAND gates NAND_<L1:LN>, and turn NAND gates NAND_<T1:TN>. The forward NAND gates NAND_<R1:RN> receive forward signals INPUT_SIG, DLY_INPUT_SIG<R1:RN−1> from a signal input node INPUT_ND or the previous unit delay blocks 500<1:N−1> and corresponding delay control codes CON<1:N>. The turn NAND gates NAND_<T1:TN> receive the forward signals DLY_INPUT_SIG<R1:RN> of the forward NAND gates NAND_<R1:RN> and the delay control codes CON<2:N+1> corresponding to the next unit delay blocks 500<2:N+1> to output turn signals T_DLY_INPUT_SIG<R1:RN>. The reverse NAND gates NAND_<L1:LN> receive reverse signals DLY_INPUT_SIG<L2:LN>, VDD from the next unit delay blocks 500<2:N> or a power supply node and the turn signals T_DLY_INPUT_SIG<R1:RN> to output to the previous unit delay blocks 500<1:N−1> or the signal output node OUTPUT_ND.

Herein, the forward NAND gate NAND_R1 provided at the first unit delay block 500<1> among the unit delay blocks 500<1:N> delays a forward signal INPUT_SIG applied through the signal input node INPUT_ND from the outside of the delay line by a predetermined time through an AND operation in response to the delay control code CON<1> corresponding to the least significant bit LSB in the delay control codes CON<1:N>, and outputs the result DLY_INPUT_SIG<R1> to the next unit delay block 500<2> and the turn NAND gate NAND_T1 provided at the corresponding unit delay block 500<1>.

Also, the forward NAND gates NAND_<R2:RN−1> provided at the unit delay blocks 500<2:N−1> other than the first unit delay block 500<1> and the last unit delay block 500<N> among the unit delay blocks 500<1:N> delay the forward signals DLY_INPUT_SIG<R1:RN−2> received from the forward NAND gates NAND_<R1:RN−2> provided at the previous unit delay blocks 500<1:N−2> by a predetermined time through an AND operation in response to the delay control codes CON<2:N−1> of the bits other than the delay control code CON<1> of the least significant bit LSB and the delay control code CON<N> of the most significant bit MSB among the delay control codes CON<1:N>, and output the results DLY_INPUT_SIG<R2:RN−1> to the next unit delay blocks 500<3:N> and the turn NAND gates NAND_<T2:TN'11> provided at the corresponding unit delay blocks 500<2:N−1>.

Also, the forward NAND gate NAND_RN provided at the last unit delay block 500<N> among the unit delay blocks 500<1:N> delays the forward signal DLY_INPUT_SIG<RN−1> received from the forward NAND gate NAND_RN−1 provided at the previous unit delay block 500<N−1> by a predetermined time through an AND operation in response to the delay control code CON<N> corresponding to the most significant bit MSB in the delay control codes CON<1:N>, and output the results DLY_INPUT_SIG<RN> to the turn NAND gate NAND_<TN> provided at the corresponding unit delay block 500<N>.

Also, the turn NAND gate NAND_TN provided at the last unit delay block 500<N> among the unit delay blocks 500<1:N> outputs the forward signal DLY_INPUT_SIG<RN> received from the forward NAND gate NAND_RN provided at the corresponding unit delay block 500<N> as the turn signal T_DLY_INPUT_SIG<RN> to the reverse NAND gate NAND_LN provided at the corresponding unit delay block 500<N> in response to an additional control code CON<N+1>. The additional control code CON<N+1> is determined corresponding to the most significant bit MSB in the delay control codes CON<1:N>.

Herein, the additional control code CON<N+1> has the same value as the delay control code CON<N> of the most significant bit MSB among the delay control codes CON<1:N>. That is, when the delay control code CON<N> of the most significant bit MSB among the delay control codes CON<1:N> has a value of ‘1’, the additional control code CON<N+1> also has a value of ‘1’ and when the delay control code CON<N> of the most significant bit MSB among the delay control codes CON<1:N> has a value of ‘0’, the additional control code CON<N+1> also has a value of ‘0’.

Also, the turn NAND gates NAND_<T1:TN−1> provided at the unit delay blocks 500<1:N−1> other than the last unit delay block 500<N> among the unit delay blocks 500<1:N> output the forward signals DLY_INPUT_SIG<1:N−1> received from the forward NAND gates NAND_<R1:RN−1> provided at the corresponding unit delay blocks 500<1:N−1> as the turn signals T_DLY_INPUT_SIG<1:N−1> to the reverse NAND gates NAND_<L1:LN−1> provided at the corresponding unit delay blocks 500<1:N−1> in response to the bit value of the delay control codes CON<2:N> applied to the forward NAND gates NAND_<R2:RN> provided at the next unit delay blocks 500<2:N>.

Also, the reverse NAND gate NAND_LN provided at the last unit delay block 500<N> among the unit delay blocks 500<1:N> delays the turn signal T_DLY_INPUT_SIG<RN> received from the turn NAND gate NAND_TN provided at the corresponding unit delay block 500<N> by a predetermined time through an AND operation, and outputs the result DLY_INPUT_SIG<LN> to the reverse NAND gate NAND_LN−1 provided at the previous unit delay block 500<N−1>.

Also, the reverse NAND gates NAND_<L2:LN−1> provided at the unit delay blocks 500<2:N−1> other than the first unit delay block 500<1> and the last unit delay block 500<N> among the unit delay blocks 500<1:N> perform an AND operation on the reverse signals DLY_INPUT_SIG<L3:LN> received from the reverse NAND gates NAND_<L3:LN> provided at the next unit delay blocks 500<3:N> and the turn signals T_DLY_INPUT_SIG<R2:RN−1> received from the turn NAND gates NAND_<T2:TN−1> provided at the corresponding unit delay blocks 500<2:N−1>, and outputs the results DLY_INPUT_SIG<L2:LN−1> to the reverse NAND gates NAND_<L1:LN−2> provided at the previous unit delay blocks 500<1:N−2>.

Also, the reverse NAND gate NAND_L1 provided at the first unit delay block 500<1> among the unit delay blocks 500<1:N> performs an AND operation on the reverse signal DLY_INPUT_SIG<L2> received from the reverse NAND gate NAND_L2 provided at the next unit delay block 500<2> and the turn signal T_DLY_INPUT_SIG<R1> received from the turn NAND gate NAND_T1 provided at the corresponding unit delay block 500<1>, and outputs the result OUTPUT_SIG through the signal output node OUTPUT_ND to the outside of the delay line.

An operation of the delay line in accordance with this embodiment of the present invention will be described below on the basis of the above configuration.

First, the delay control codes CON<1:N> include a plurality of bits and the delay control code CON<1> of the least significant bit LSB to the delay control code CON<N> of the most significant bit MSB may sequentially have a value of ‘1’.

For example, when the delay control code CON<5> of the fifth bit among the delay control codes CON<1:N> has a value of ‘1’, the delay control code CON<1> of the least significant bit LSB to the delay control code CON<5> of the fifth bit unconditionally have a value of ‘1’.

Also, the number of the unit delay blocks that pass the input signal INPUT_SIG among the unit delay blocks 500<1:N> increases as the number of the bits having a value of ‘1’ in the delay control codes CON<1:N> increases.

For example, when the delay control code CON<1> of the least significant bit LSB to the delay control code CON<5> of the fifth bit have a value of ‘1’, only the first to fifth unit delay blocks 500<1:5> among the unit delay blocks 500<1:N> are used to delay the input signal INPUT_SIG; and when the delay control code CON<1> of the least significant bit LSB to the delay control code CON<7> of the seventh bit have a value of ‘1’, the first to seventh unit delay blocks 500<1:7> among the unit delay blocks 500<1:N> are used to delay the input signal INPUT_SIG. Therefore, when the delay control code CON<1> of the least significant bit LSB to the delay control code CON<7> of the seventh bit have a value of ‘1’, the delay value of the input signal INPUT_SIG is larger than the delay value of the input signal INPUT_SIG when the delay control code CON<1> of the least significant bit LSB to the delay control code CON<5> of the fifth bit have a value of ‘1’.

Also, the forward NAND gates NAND_<R1:RN> provided respectively at the unit delay blocks 500<1:N> delay the forward signals INPUT_SIG, DLY_INPUT_SIG<R1:RN−1> received from the signal input node INPUT_ND or the previous unit delay blocks 500<1:N−1> by a first predetermined time in an activation period of the delay control codes CON<1:N> corresponding to the corresponding unit delay blocks 500<1:N>, to output the result DLY_INPUT_SIG<R1:RN>.

Also, the turn NAND gates NAND_<T1:TN> provided respectively at the unit delay blocks 500<1:N> output the output signals DLY_INPUT_SIG<R1:RN> of the forward NAND gates NAND_<R1:RN> as the turn signals T_DLY_INPUT_SIG<R1:RN> in an activation period of the delay control codes CON<1:N+1> corresponding to the next unit delay blocks 500<2:N+1>, and output the turn signals T_DLY_INPUT_SIG<R1:RN> in a deactivation state in a deactivation period of the delay control codes CON<1:N+1> corresponding to the next unit delay blocks 500<2:N+1>.

Also, the reverse NAND gates NAND_<L1:LN> provided respectively at the unit delay blocks 500<1:N> delay the reverse signals VDD, DLY_INPUT_SIG<L2:LN> received from the power voltage node VDD or the next unit delay blocks 500<2:N> by a second predetermined time in a deactivation period of the turn signals T_DLY_INPUT_SIG<R1:RN>, and output the result to the previous unit delay blocks 500<1:N−1> or the signal output node OUTPUT_ND.

Also, the reverse NAND gates NAND_<L1:LN> provided respectively at the unit delay blocks 500<1:N> delay the turn signals T_DLY_INPUT_SIG<R1:RN> by the second predetermined time in a deactivation period of the reverse signals VDD, DLY_INPUT_SIG<L2:LN> received from the power voltage node VDD or the next unit delay blocks 500<2:N>, and output the result to the previous unit delay blocks 500<1:N−1> or the signal output node OUTPUT_ND.

Herein, the forward NAND gates NAND_<R1:RN> provided respectively at the unit delay blocks 500<1:N> delay signals received in response to the delay control codes CON<1:N> by the first predetermined time, and the reverse NAND gates NAND_<L1:LN> provided respectively at the unit delay blocks 500<1:N> delay signals received corresponding to the delay control codes CON<1:N> by the second predetermined time. Herein, since the first predetermined time and the second predetermined time are generated by the AND operations of the NAND gates, they may vary according to the design methods.

That is, when the forward NAND gates NAND_<R1:RN> and the reverse NAND gates NAND_<L1:LN> are designed to have different sizes, the first predetermined time and the second predetermined time are different from each other.

However, when the forward NAND gates NAND_<R1:RN> and the reverse NAND gates NAND_<L1:LN> are designed to have the same size, the first predetermined time and the second predetermined time are identical to each other.

For reference, although the turn NAND gates NAND_<T1:TN> provided respectively at the unit delay blocks 500<1:N> also perform an AND operation, it is assumed that they do not cause time consumption. The reason for this is that the respective turn NAND gates NAND_<T1:TN> at the respective unit delay blocks 500<1:N> serve to set the transfer paths of the inputted signals. Practically, since the AND operation causes some time consumption, a semiconductor memory device must be fabricated in consideration of the time consumption of the respective NAND gates NAND_<T1:TN>.

Specifically, when the input signal INPUT_SIG is applied from the outside of the delay line through the signal input node INPUT_ND connected to the forward NAND gate NAND_R1 provided at the first unit delay block 500<1> among the unit delay blocks 500<1:N>, the delay degree of the input signal INPUT_SIG is determined according to the delay control codes CON<1:N>.

For example, when only the delay control code CON<1> of the least significant bit LSB to the delay control code CON<5> of the fifth bit among the delay control codes CON<1:N> have a value of ‘1’ and the delay control codes CON<6:N> of the other bits have a value of ‘0’, the forward NAND gates NAND_<R1:R5> provided at the first to fifth unit delay blocks 500<1:5> transfer the input signal INPUT_SIG as the first to fifth forward signals DLY_INPUT_SIG<R1:R5> by sequentially delaying it the first predetermined time, and the turn NAND gate NAND_<T1:T4> provided at the first to fourth unit delay blocks 500<1:4> deactivate the first to fourth turn signals T_DLY_INPUT_SIG<R1:R4> to a logic high level and maintain their state in response to inversion of the delay control codes CON<2:5>. However, the turn NAND gate NAND_T5 provided at the fifth unit delay block 500<5> outputs the fifth forward signal DLY_INPUT_SIG<R5> as the fifth turn signal T_DLY_INPUT_SIG<R5> in response to inversion of the delay control code CON<6>. Therefore, the reverse NAND gate NAND_L5 provided at the fifth unit delay block 500<5> outputs the fifth turn signal T_DLY_INPUT_SIG<R5> as the fifth reverse signal DLY_INPUT_SIG<L5> by delaying the same by the second predetermined time, and the reverse NAND gates NAND_<L4:L1> provided at the fourth to first unit delay blocks 500<4:1> transfer the fifth reverse signal DLY_INPUT_SIG<L5> as the fourth to first reverse signals DLY_INPUT_SIG<L4:L2>, OUTPUT_SIG by sequentially delaying the same by the second predetermined time.

Also, the reverse NAND gates NAND_<L6:LN>, the turn NAND gates NAND_<T6:TN> and the forward NAND gates NAND_<R6:RN> provided at the unit delay blocks 500<6:N> other than the first to fifth unit delay blocks 500<1:5> among the unit delay blocks 500<1:N> do not perform any operation.

In this way, the input signal INPUT_SIG applied through the signal input node INPUT_ND from the outside of the delay line in accordance with this embodiment of the present invention is delayed sequentially through the forward NAND gates NAND_<R1:RN> provided at the unit delay blocks 500<1:N> and is again delayed sequentially through the reverse NAND gates NAND_<L1:LN> provided at the unit delay blocks 500<1:N>, so that the resultant signal is outputted through the signal output node OUTPUT_ND. Herein, the number of the unit delay blocks passing the input signal INPUT_SIG varies according to the delay control codes CON<1:N>.

Thus, the delay line in accordance with this embodiment of the present invention can freely control the delay value of the input signal INPUT_SIG by freely controlling the number of the unit delay blocks among the unit delay blocks 500<1:N> to delay the input signal INPUT_SIG according to the delay control codes CON<1:N>, and can freely change the total number of the unit delay blocks 500<1:N> included in the delay line by controlling the value of ‘N’. Therefore, the maximum delay value of the delay line can be freely controlled according to the value of ‘N’.

Also, since only one signal input node INPUT_ND and one signal output node OUTPUT_ND are used, even though the total length of the delay line increases with an increase in the value of ‘N’, the loading on the signal input node INPUT_ND and the loading on the signal output node OUTPUT_ND always have the same value. Thus, the response speed of the delay line can always maintain the same value regardless of its length, so that the delay line in accordance with this embodiment of the present invention can operate stably even in a semiconductor memory device that operates at high speeds.

As described above, this embodiment of the present invention can freely determine the delay value of the input signal INPUT_SIG in the delay line according to the delay control codes CON<1:N> and can freely control the maximum delay value of the delay line according to the value of ‘N’, thus making it possible to freely delay the input signal INPUT_SIG over a wide variation range.

Also, only one signal input node INPUT_ND and one signal output node OUTPUT_ND are used to delay the input signal INPUT_SIG, thereby minimizing the amount of loading on the signal input node INPUT_ND and the signal output node OUTPUT_ND. This makes it possible for the delay line to have a high response speed.

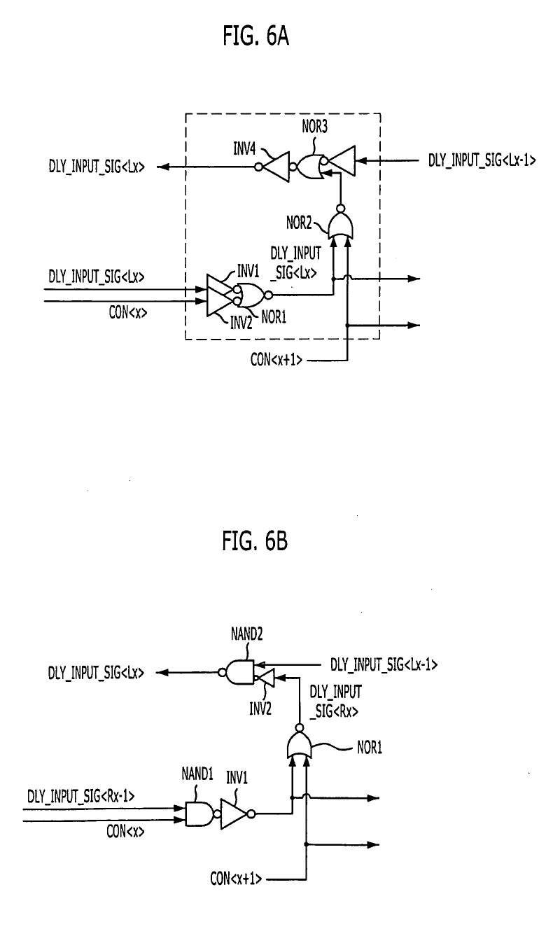

FIGS. 6A and 6B are circuit diagrams of the unit delay block provided in the delay line in accordance with an embodiment of the present invention.

Referring to FIG. 6A, the unit delay block 500<x> provided at the delay line in accordance with this embodiment of the present invention includes four inverters INV1 to INV4 and three NOR gates NOR1 to NOR3

Referring to FIG. 6B, the unit delay block 500<x> provided at the delay line in accordance with this embodiment of the present invention includes two NAND gates NAND1 to NAND2, one NOR gate NOR, and two inverters INV1 to INV2.

As illustrated in FIGS. 6A and 6B, the unit delay blocks provided at the delay line in accordance with this embodiment of the present invention may be implemented in various methods using various logic units.

As described above, the present invention delays the input signal over a wide variation range and delays the input signal by means of only one input node and one output node, thereby making it possible to minimize the amount of loading on the input node and the output node.

Therefore, the delay line of the present invention can have a high response speed while delaying the input signal over a wide variation range.

While the present invention has been described with respect to the specific embodiments, it will be apparent to those skilled in the art that various changes and modifications may be made without departing from the spirit and scope of the invention as defined in the following claims. For example, the logic gates and the transistors exemplified in the aforesaid embodiments may be implemented to have different positions and types according to the polarities of the inputted signals.

What is claimed is:

1. A delay line, comprising:
a forward delay unit configured to determine the length of a forward delay path passing an input signal in response to a delay control code;
a reverse delay unit configured to receive an output signal of the forward delay unit, and to output a delayed input signal through a reverse delay path that is as long as the length of the forward delay path determined by the delay control code; and
a transfer unit configured to transfer the output signal of the forward delay unit from a turn point determined by the delay control code to the reverse delay unit.

2. The delay line of claim 1, wherein the forward delay unit is configured to receive the input signal through a signal input node, to pass the received input signal through the forward delay path whose length varies in response to the delay control code, and to output the result to the transfer unit.

3. The delay line of claim 2, wherein the length of the forward delay path varies by a unit delay in response to the value of the delay control code.

4. The delay line of claim 1, wherein the reverse delay unit is configured to receive the output signal of the forward delay unit from the transfer unit at the turn point, to pass the received signal through the reverse delay path corresponding to the delay control code, and to output the result to a signal output node.

5. The delay line of claim 4, wherein the length of the reverse delay path varies by a unit delay in response to the value of the delay control code.

6. The delay line of claim 1, wherein the forward delay path and the reverse delay path, whose lengths are determined by the delay control code, have the same delay value.

7. The delay line of claim 1, wherein the forward delay path and the reverse delay path, whose lengths are determined by the delay control code, have different delay values.

8. A delay line, comprising:
a plurality of chain-connected unit delay blocks, each of said plurality of chain-connected unit delay blocks comprising:
a forward delay unit configured to delay an input signal received from a previous unit delay block of the plurality of chain-connected unit delay blocks in response to a delay control code corresponding to the unit delay block; and
a reverse delay unit configured to delay an input signal received from the forward delay unit or a next unit delay block of the plurality of chain-connected unit delay blocks in response to a delay control code corresponding to the next unit delay block.

9. The delay line of claim 8, wherein the forward delay unit provided at the first unit delay block among the unit delay blocks is configured to delay the input signal received from an signal input node by a predetermined time in response to the least significant bit in the delay control code, and to output the result to the next unit delay block and the reverse delay unit provided at the corresponding unit delay block.

10. The delay line of claim 8, wherein each of the forward delay units provided at the unit delay blocks other than the first unit delay block and the last unit delay block among the unit delay blocks is configured to delay the input signal received from the forward delay unit provided at the previous unit delay block by a predetermined time in response to the bits other than the least significant bit and the most significant bit in the delay control code, and to output the result to the next unit delay block and the reverse delay unit provided at the corresponding unit delay block.

11. The delay line of claim 8, wherein the forward delay unit provided at the last unit delay block among the unit delay blocks is configured to delay the input signal received from the forward delay unit provided at the previous unit delay block by a predetermined time in response to the most significant bit in the delay control code, and to output the result to the reverse delay unit provided at the corresponding unit delay block.

12. The delay line of claim 8, wherein the reverse delay unit provided at the last unit delay block among the unit delay blocks is configured to delay the input signal received from the forward delay unit provided at the corresponding unit delay block by a predetermined time in response to an additional control code determined corresponding to the most significant bit in the delay control code, and to output the result to the previous unit delay block.

13. The delay line of claim 12, wherein the additional control code has the same value as the most significant bit in the delay control code.

14. The delay line of claim 8, wherein each of the reverse delay units provided at the unit delay blocks other than the first unit delay block and the last unit delay block among the unit delay blocks is configured to delay the input signal received from the reverse delay unit provided at the next unit delay block or the input signal received from the forward delay unit provided at the corresponding unit delay block by a predetermined time in response to the bit value of the delay control code corresponding to the next unit delay block, and to output the result to the previous unit delay block.

15. The delay line of claim 8, wherein the reverse delay unit provided at the first unit delay block among the unit delay block is configured to delay the input signal received from the reverse delay unit provided at the next unit delay block or the input signal received from the forward delay unit provided at the corresponding unit delay block by a predetermined time in response to the bit value of the delay control code corresponding to the next unit delay block, and to output the result to a signal output node.

16. The delay line of claim 8, wherein the delay value corresponding to the forward delay unit and the delay value corresponding to the reverse delay unit are identical to each other.

17. The delay line of claim 8, wherein the delay value corresponding to the forward delay unit and the delay value corresponding to the reverse delay unit are different from each other.

18. A delay line, comprising:
a plurality of chain-connected unit delay blocks, each of said plurality of chain-connected unit delay blocks comprising:
a forward transfer unit configured to output an input signal or a forward signal received from a previous unit delay block of the plurality of chain-connected unit delay blocks in response to a delay control code corresponding to the corresponding unit delay block;
a reverse transfer unit configured to output a reverse signal received from a next unit delay block of the plurality of chain-connected unit delay blocks or a turn signal to the previous unit delay block; and
a turn transfer unit configured to output an output signal of the forward transfer unit as the turn signal in response to a delay control code corresponding to the next unit delay block.

19. The delay line of claim 18, wherein the forward transfer unit provided at the first unit delay block among the unit delay blocks is configured to delay the forward signal received from an signal input node by a predetermined time in response to the least significant bit in the delay control code, and to output the result to the next unit delay block and the turn transfer unit provided at the corresponding unit delay block.

20. The delay line of claim 18, wherein each of the forward transfer units provided at the unit delay blocks other than the first unit delay block and the last unit delay block among the unit delay block is configured to delay the forward signal received from the forward transfer unit provided at the previous unit delay block by a predetermined time in response to the bits other than the least significant bit and the most significant bit in the delay control code, and to output the result to the next unit delay block and the turn transfer unit provided at the corresponding unit delay block.

21. The delay line of claim 18, wherein the forward transfer unit provided at the last unit delay block among the unit delay blocks is configured to delay the forward signal received from the forward transfer unit provided at the previous unit delay block by a predetermined time in response to the most significant bit in the delay control code, and to output the result to the turn transfer unit provided at the corresponding unit delay block.

22. The delay line of claim 18, wherein the turn transfer unit provided at the last unit delay block among the unit delay blocks is configured to output the forward signal received from the forward transfer unit provided at the corresponding unit delay block as the turn signal to the reverse transfer unit provided at the corresponding unit delay block in response to an additional control code determined to correspond to the most significant bit in the delay control code.

23. The delay line of claim 22, wherein the additional control code has the same value as the most significant bit in the delay control code.

24. The delay line of claim 18, wherein each of the turn transfer units provided at the unit delay blocks other than the last unit delay block among the unit delay blocks is configured to output the forward signal received from the forward transfer unit provided at the corresponding unit delay block as the turn signal to the reverse transfer unit provided at the corresponding unit delay block in response to the bit value of the delay control code applied to the next unit delay block.

25. The delay line of claim 18, wherein the reverse transfer unit provided at the last unit delay block among the unit delay blocks is configured to receive a signal from a power supply node and delay the turn signal received from the turn transfer unit provided at the corresponding unit delay block by a predetermined time, and to output the result to the reverse transfer unit provided at the previous unit delay block.

26. The delay line of claim 18, wherein each of the reverse transfer units provided at the unit delay blocks other than the first unit delay block and the last unit delay block among the unit delay blocks is configured to delay the reverse signal received from the reverse transfer unit provided at the next unit delay blocks and the turn signal received from the turn transfer unit provided at the corresponding unit delay block by a predetermined time, and to output the result to the reverse transfer unit provided at the previous unit delay block.

27. The delay line of claim 18, wherein the reverse transfer unit provided at the first unit delay block among the unit delay blocks is configured to delay the reverse signal received from the reverse transfer unit provided at the next unit delay block and the turn signal received from the turn transfer unit provided at the corresponding unit delay block by a predetermined time, and to output the result to an signal output node.

28. The delay line of claim 18, wherein the forward transfer unit is configured to delay the forward signal received from the previous unit delay block by a first predetermined time in the activation period of the delay control code corresponding to the corresponding unit delay block prior to output.

29. The delay line of claim 28, wherein the turn transfer unit is configured to output an output signal of the forward transfer unit as the turn signal in the deactivation period of the delay control code corresponding to the next unit delay block, and to output the turn signal in a deactivation state in the activation period of the delay control code corresponding to the next unit delay block.

30. The delay line of claim 29, wherein the reverse transfer unit is configured to delay the reverse signal received from the next unit delay block by a second predetermined time in the deactivation period of the turn signal, and to output the result to the previous unit delay block.

31. The delay line of claim 29, wherein the reverse transfer unit is configured to delay the turn signal by a second predetermined time in the deactivation period of the reverse signal received from the next unit delay block, and to output the result to the previous unit delay block.

32. The delay line of claim 30, wherein the first predetermined time and the second predetermined time are identical to each other.

33. The delay line of claim 30, wherein the first predetermined time and the second predetermined time are different from each other.

34. A method for operating a delay line including a plurality of chain-connected unit delay blocks, each having a forward input node, a forward output node, a reverse input node, and a reverse output node, the method, comprising:
outputting a signal applied to the forward input node to the forward output node in response to a delay control code corresponding to the corresponding unit delay block;
outputting a signal applied to the reverse input node to the reverse output node; and
outputting a signal applied to the forward output node to the reverse input node in response to a delay control code corresponding to the next unit delay block.

35. The method of claim 34, wherein outputting the signal to the forward output node, includes:
delaying the signal applied to the forward input node by a predetermined time in the activation period of the delay control code corresponding to the corresponding unit delay block and outputting the result to the forward output node; and
fixing the level of the forward output node at a deactivation state in the deactivation period of the delay control code corresponding to the corresponding unit delay block regardless of the signal applied to the forward input node.

36. The method of claim 34, wherein outputting the signal to the reverse input node includes:
outputting the signal applied to the forward output node to the reverse input node in the deactivation period of the delay control code corresponding to the next unit delay block.

37. The method of claim 34, wherein outputting the signal to the forward output node includes delaying the signal applied to the forward input node by a first predetermined time in response to the delay control code corresponding to the corresponding unit delay block and outputting the result to the forward output node.

38. The method of claim 37, wherein outputting the signal to the reverse output node includes delaying the signal applied to the reverse input node by a second predetermined time and outputting the result to the reverse output node.

39. The method of claim 38, wherein the first predetermined time and the second predetermined time are identical to each other.

40. The method of claim 38, wherein the first predetermined time and the second predetermined time are different from each other.
